(19) United States
(12) Patent Application Publication
(10) Pub. No.: US 2019/0139852 A1
(43) Pub. Date: May 9, 2019

(54) EMBEDDED THERMAL ENHANCEMENT STRUCTURES FOR MOLDED INTEGRATED CIRCUIT PACKAGES

(71) Applicant: QUALCOMM Incorporated, San Diego, CA (US)

(72) Inventors: Youmin YU, San Diego, CA (US); Nader NIKFAR, San Diego, CA (US); Ryan LANE, San Diego, CA (US)

(21) Appl. No.: 15/804,250

(22) Filed: Nov. 6, 2017

(51) Int. Cl. H01L 23/367; H01L 23/31; H01L 23/373; H01L 21/56

(52) U.S. Cl. CPC H01L 23/367; H01L 21/563; H01L 23/3736; H01L 23/3121

(57) ABSTRACT

A semiconductor package includes a substrate, a die coupled to the substrate, the die being smaller in size than the substrate and placed on top of the substrate, a mold formed around and over the die, the mold having a top surface and a mold volume, wherein the mold includes at least one of thermally conductive fin and pillar formed within the mold volume to enhance heat transfer within the package, and a film layer formed over the top surface of the mold volume. The mold includes a plurality of grooves and holes formed above and around the die, and a thermally conductive material is filled into the grooves and holes forming at least one of thermally conductive fin and pillar within the mold volume.

### BACKGROUND

### Field

Aspects of the present disclosure relate generally to thermal dissipation and, more specifically, to thermal dissipation in semiconductor packages.

### Background

Thermal problems are continually getting harder to solve, for example, in the mobile device market, as performance and use cases go up from a power distribution perspective, and advanced silicon node leads to smaller die and larger mold volume. This can be attributable to the small form factor used in mobile devices inhibiting on-die heat from the package. As such, there is a constant need in the industry to improve thermal dissipation for semiconductor packages.

### SUMMARY

The following presents a simplified summary of one or more embodiments to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

A method of manufacturing a semiconductor package according to one aspect is described. The method may include providing a die coupled to a substrate, the die being smaller in size than the substrate and placed on top of the substrate; forming a mold around and over the die, the mold having a top surface and a mold volume; forming grooves and holes in the mold; filling at least some of the grooves and holes with a thermally conductive material forming at least one of thermally conductive fin and pillar within the mold volume; and forming a film layer over the top surface of the mold volume.

A semiconductor package according to one aspect is described. The package may include a substrate; a die coupled to the substrate, the die being smaller in size than the substrate and placed on top of the substrate; and a mold formed around and over the die, the mold having a top surface and a mold volume, wherein the mold includes at least one of thermally conductive fin and pillar formed within the mold volume; and a film layer formed on the top surface of the mold.

These and other aspects of the invention will become more fully understood upon a review of the detailed description, which follows. Other aspects, features, and embodiments of the invention will become apparent to those of ordinary skill in the art, upon reviewing the following description of specific, exemplary embodiments of the invention in conjunction with the accompanying figures.

### BRIEF DESCRIPTION OF THE DRAWINGS

FIG. 1 shows a cross-sectional view of a semiconductor package of the prior art;

FIG. 2 shows a cross-sectional view of a semiconductor package of the prior art;

FIGS. 3A-3B show a cross-sectional view and a top view, respectively, of a semiconductor package according to one aspect of the invention; and

FIGS. 4A-4D show a process of manufacturing a semiconductor package according to one aspect of the invention.

### DETAILED DESCRIPTION

The detailed description set forth below, in connection with the appended drawings, is intended as a description of various aspects and is not intended to represent the only aspects in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

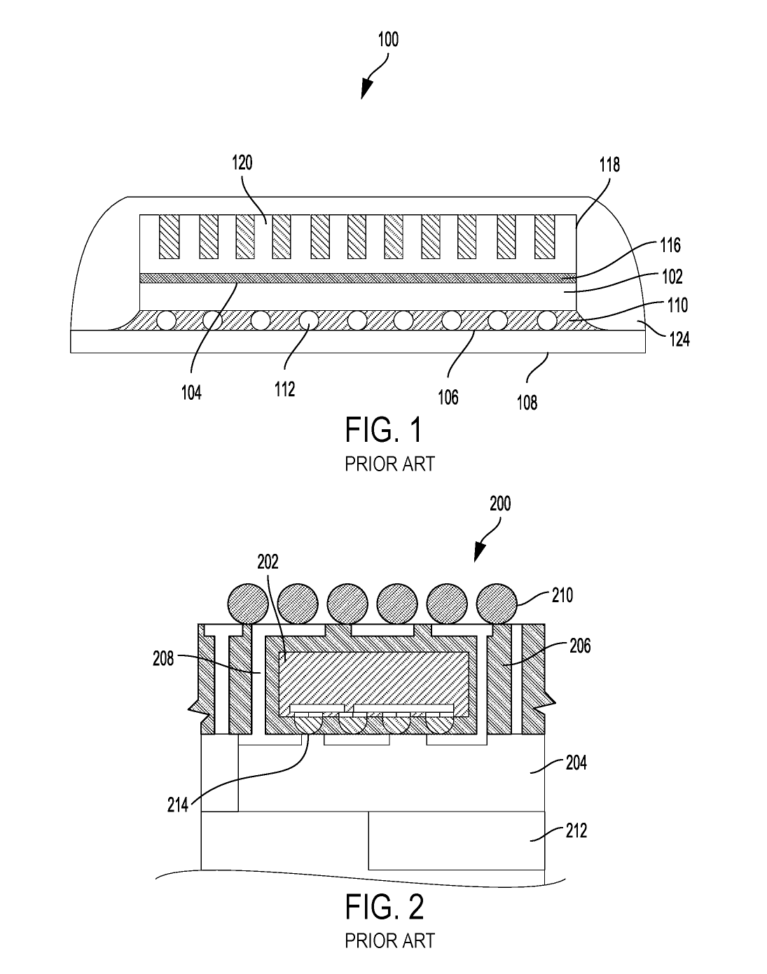

FIG. 1 shows a cross-sectional view of a semiconductor package 100 of the prior art using a heat spreader 118. The package 100 may comprise an integrated circuit (IC) die 102, a package substrate 108, die attach and/or underfill adhesive 110, a plurality of humps 112, a backside metallization layer 116, and molding compound 124. The IC die 102 may undergo a series of etching and deposition steps to fabricate circuitry upon the semiconductor substrate of the die 102. The die attach and/or underfill adhesive 110 may help secure the die 102 to the substrate 108. The back surface 104 of the die 102 faces away from a top surface 106 of the substrate 108. The back surface 104 includes the backside metallization layer 116 that couples to the heat spreader 118. The heat spreader 118 may further include fins 120 that help dissipate heat generated by the die 102. In high performance small form factor devices, implementing the heat spreader 118, as shown in FIG. 1, may not be practical or possible due to size constraints.

FIG. 2 shows a cross-sectional view of a semiconductor package 200 of the prior art. The chip package 200 may comprise an IC die 202, a wafer 204, a mold compound 206, and a plurality of bumps 214. Examples of the die 202 include a semiconductor die (e.g., a silicon die), a MicroElectroMechanical Systems (MEMS) die, and a passive die (e.g., a passive glass die). Connections are provided to the die 202 and/or the wafer 204 using pillars 208 formed of conductive material (e.g., copper, gold, and so forth), which extend through the mold compound 206. For example, the pillars 208 can be electrically and/or thermally connected to integrated circuits provided with the die 202 and/or the wafer 204. In some implementations, the pillars 208 can be connected to the die 202 to provide thermal management of a package. The pillars 208 can be thermally connected to a heat sink (e.g., an external heat sink 212), a thermal pad, and so forth for transferring heat from the die 202 and/or the wafer 204. For example, solder balls 210 are connected to pillars 208, which are connected to wafer 204, which is connected to heat sink 212. In this manner, a continuous path for heat dissipation is provided from the die 202 to the wafer 204. In high performance, small form factor devices, implementing the technique of forming pillars through the mold and connecting the pillars to the heat sink as shown in FIG. 2 may not be practical or possible due to size constraints. In particular, while there have been thermal enhancements within the package, around the package, and underneath the die within the package, there is a need to improve package thermal performance within the mold volume.

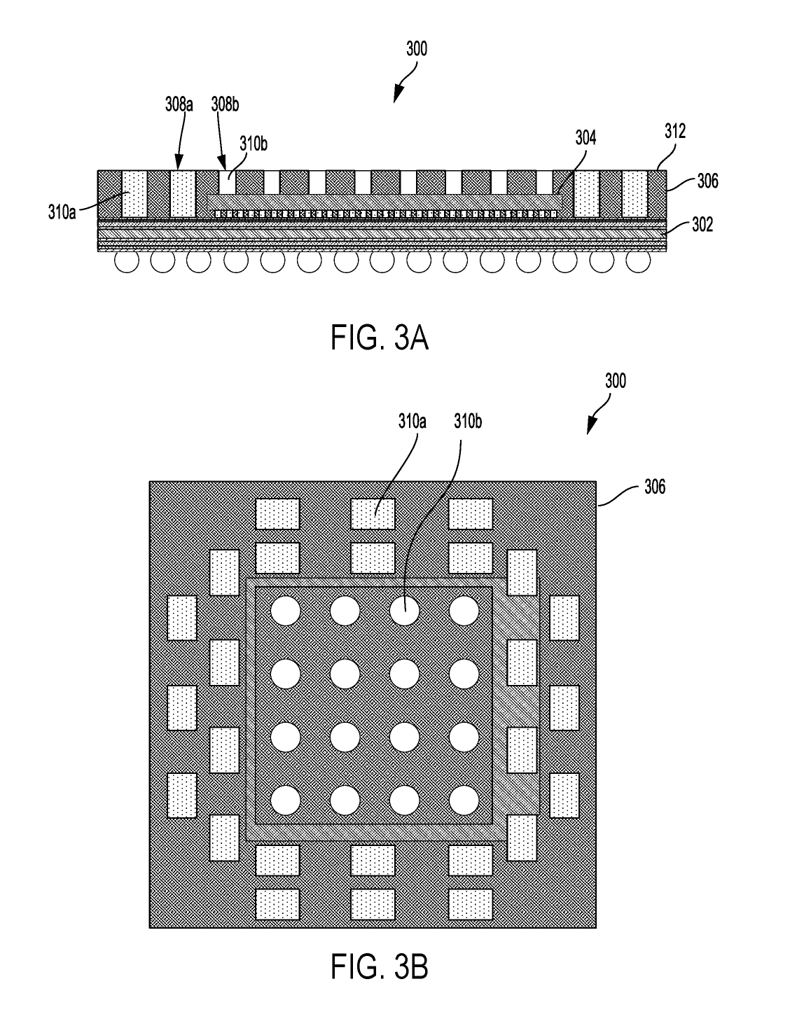

Referring to FIG. 3A, there is shown a cross-sectional view of a semiconductor package 300 of one aspect of the invention. The semiconductor package 300 may include a substrate 302, a die 304 coupled to the substrate 302, the die being smaller in size than the substrate 302 and placed above the substrate 302, and a mold 306 formed around and/or above the die 304, the mold having a top surface and a mold volume. The mold 306 may further include at least one of a thermally conductive fin 308a and/or pillar 308b formed within the mold volume. The fins 308a and pillars 308b are formed in grooves 310a and holes 310b, respectively, as further described below. The semiconductor package may further comprise a film layer 312 formed over the top surface of the mold volume.

Referring to FIG. 3B, there is shown a top view of the semiconductor package 300 of one aspect of the invention. The mold 306 may further include a plurality of grooves 310a and holes 310b, which are formed in the mold 306 and then filled with thermally conductive materials forming at least one of thermally conductive fins 308a and pillars 308b within the mold volume as further described below. By introducing thermally conductive pillar structures in the mold volume, this enhances heat transfer within the package. The plurality of grooves 310a and holes 310b may be around and/or above the die 304 extending to the substrate 302 and to the top surface of the mold volume.

The film layer 312 formed over the top surface of the mold volume protects the pillar structures, e.g., the at least one of thermally conductive fins 308a and pillars 308b, and may be used for product marking purposes. In another aspect, the at least one of conductive fins and pillars 308 has different cross-sectional shapes. The cross-sectional shapes can be any shape including at least one of round, oval, square, rectangular, triangle, diamond, star, and so forth. In another aspect, the at least of one conductive fins 308a and pillars 308b may have varying heights from one another. The heights can be the height between a substrate top surface and a mold volume top surface, and the height between a die top surface and the mold volume top surface. In another aspect, the at least one of conductive fins 308a and pillars 308b may have different pitches. In another aspect, the at least one of conductive fins 308a and pillars 308b may have different layout patterns. In another aspect, the at least one of conductive fins 308a and pillars 308 may have different thermally conductive materials. The thermally conductive materials may comprise one or more metallic pieces, alloys, and polymers. The thermally conductive materials may comprise at least one of copper, aluminum, magnesium, and other metal alloys.

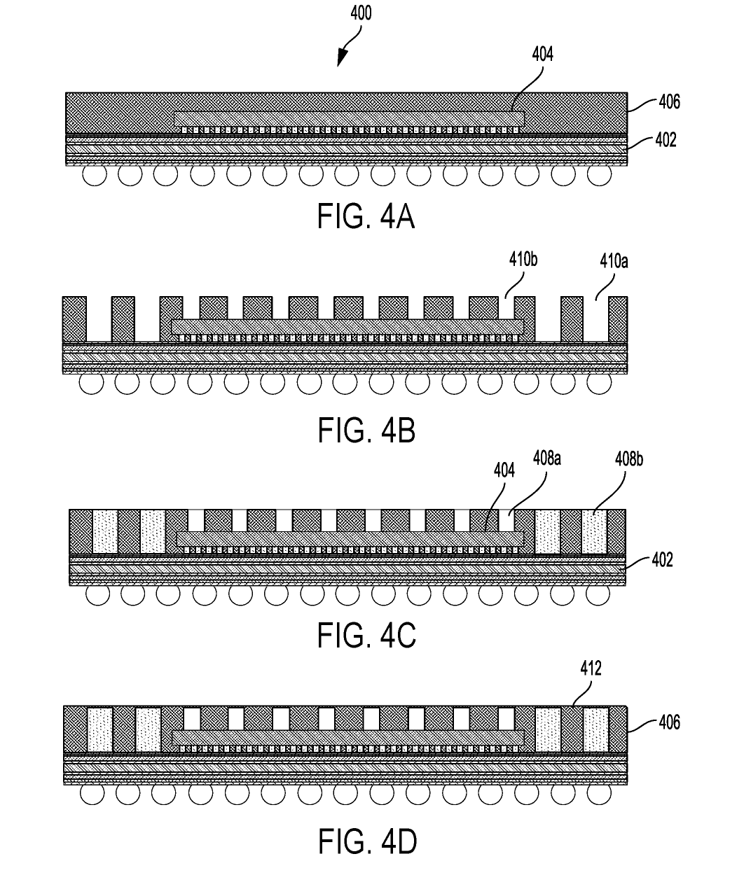

Referring to FIGS. 4A-4D, there is shown a process of manufacturing a semiconductor package 400 in accordance to one aspect of the invention. First, substrate 402 is provided with a die 404 coupled to the substrate 402, the die 404 being smaller in size than the substrate 402 and placed above the substrate 402. Next, a mold 406 is formed around and over the die 404 as shown in FIG. 4A, the mold having a top surface and a mold volume. A plurality of grooves 410a and holes 410b are then formed in the mold 406 as shown in FIG. 4B. The plurality of grooves 410a and holes 410b may be formed around and/or above the die 404, and extend to the substrate 402 and to a film layer 412 (which is further discussed below). The plurality of grooves 410a and holes 410b are then filled with thermally conductive materials forming at least one of thermally conductive fins 408a and pillars 408b, respectively, within the mold volume as shown in FIG. 4C. By introducing thermally conductive pillar structures in the mold volume, this enhances heat transfer within the package. Next, a film layer 412 is then formed over the top surface of the mold volume to protect the conductive fins and pillars and may be used for product marking purposes, as shown in FIG. 4D. In another aspect, the at least one of conductive fins 408a and pillars 408b may have different cross-sectional shapes. The cross-sectional shapes can be any shape including at least one of round, oval, square, rectangular, triangle, diamond, star and so forth. In another aspect, the at least of one conductive fins 408a and pillars 408b may have varying heights from one another. The heights can be the height between a substrate top surface and the mold volume top surface, and the height between a die top surface and the mold volume top surface. In another aspect, the at least one of conductive fins 408a and pillars 408b may have different pitches. In another aspect, the at least one of conductive fins 408a and pillars 408b may have different layout patterns. In another aspect, the at least one of conductive fins 408a and pillars 408 may have different thermally conductive materials. The thermally conductive materials may comprise one or more metallic pieces, alloys, and polymers. The thermally conductive materials may comprise at least one of copper, aluminum, magnesium, and other metal alloys.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a die may be coupled to a substrate in a package even though the die is never directly physically in contact with the substrate.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of a list of items” refers to any combination of those items, including single members. As an example, “at least one of a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for”.

1-11. (canceled)

12. A semiconductor package, comprising:
a substrate;
a die coupled to the substrate, the die being smaller in size than the substrate and placed on top of the substrate; and
a mold formed around and over the die, the mold having a top surface and a mold volume,
wherein the mold includes a plurality of thermally conductive fins formed within the mold volume, and
wherein the mold includes a plurality of holes above the die.

13. The semiconductor package of claim 12,
wherein a thermally conductive material is filled into the holes forming the plurality of thermally conductive fins within the mold volume.

14. (canceled)

15. The semiconductor package of claim 12, further comprising a film layer formed over the top surface of the mold volume.

16. The semiconductor package of claim 15, wherein at least one of the plurality of thermally conductive fins has a different cross-sectional shape from another thermally conductive fin.

17. The semiconductor package of claim 13, wherein at least one of the plurality of thermally conductive fins has a different height from another thermally conductive fin.

18. The semiconductor package of claim 13, wherein at least one of the plurality of thermally conductive fins has a different pitch from another thermally conductive fin.

19. The semiconductor package of claim 13, wherein at least one of the plurality of thermally conductive fins has a different layout pattern from another thermally conductive fin.

20. The semiconductor package of claim 13, wherein at least one of the plurality of thermally conductive fins has a different thermally conductive material from another thermally conductive fin.

21. The semiconductor package of claim 20, wherein the thermally conductive material comprises at least one of metallic pieces, alloys, and/or polymers.

22. The semiconductor package of claim 21, wherein the thermally conductive material comprises at least one of copper, aluminum, magnesium, and other metal alloys.

23. The semiconductor package of claim 17, wherein the height can be the height between a substrate top surface and the mold top surface, and the height between a die top surface and the mold top surface.

24. The semiconductor package of claim 16, wherein the cross-sectional shape can be any shape including at least one of round, oval, square, rectangular, triangle, diamond, and star.
